(19) United States
(12) Patent Application Publication
(10) Pub. No.: US 2026/0205056 A1
(43) Pub. Date: Jul. 16, 2026

(54) SINGLE DOWN CONVERSION SATELLITE PAYLOAD WITH POLYPHASE MIXER

(71) Applicant: Viasat, Inc., Carlsbad, CA (US)

(72) Inventors: Chi W. SHUM, Chandler, AZ (US); Alberto RODRIGUEZ, Land O Lakes, FL (US)

(21) Appl. No.: 19/136,812

(22) PCT Filed: Dec. 8, 2023
(86) PCT No.: PCT/US2023/083145

§ 371 Date: Jun. 6, 2025

Related U.S. Application Data
(60) Provisional application No. 63/386,788, filed on Dec. 9, 2022.

(51) Int. Cl. H03D 7/12; H03F 3/24; H03H 11/16; H04B 1/12; H04B 1/59

(52) U.S. Cl. CPC H03D 7/12; H03F 3/245; H03H 11/16; H04B 1/126; H04B 1/59; H03F 2200/294; H03F 2200/451

(57) ABSTRACT

Methods, systems, and devices for implementing a single down conversion satellite payload with a polyphase mixer is described.

### CROSS REFERENCE

The present Application is a 371 national phase filing of International Patent Application No. PCT/US2023/083145 by SHUM et al. entitled, “SINGLE DOWN CONVERSION SATELLITE PAYLOAD WITH POLYPHASE MIXER”, filed Dec. 8, 2023, and to U.S. Provisional Patent Application No. 63/386,788 by SHUM et al., entitled “SINGLE DOWN CONVERSION SATELLITE PAYLOAD WITH POLYPHASE MIXER” filed Dec. 9, 2022, each of which is assigned to the assignee hereof and each of which is incorporated by reference herein, in its entirety.

### BACKGROUND

The following relates generally to communications, including single down conversion satellite payload with polyphase mixer.

In some examples, a transponder may be capable of receiving a first signal and emitting a second signal in response. The transponder may, for instance, receive the first signal over a first range of frequencies and may emit the second signal over a second range of frequencies different from the first range of frequencies. A first device may transmit the first signal and a second device may receive the second signal. In order to generate the second signal, the transponder may amplify the first signal and may mix the first signal with a third signal generated by a local oscillator. Performing the amplifying and mixing may introduce distortions into the second signal not present in the first signal. As the second signal becomes more distorted, the second device may be less likely to correctly decode the second signal, thus decreasing the efficiency of communications between the first device and the second device.

### SUMMARY

The described techniques relate to improved methods, systems, devices, and apparatuses that support single down conversion satellite payload with polyphase mixer. For example, the described techniques provide for a satellite transponder to suppress mixing products within a band of a transmit signal. For instance, the satellite transponder may amplify a first signal at a low noise amplifier of the satellite transponder and generate, at a local oscillator of the satellite transponder, an oscillator signal at an oscillator frequency. The satellite transponder may divide a first signal among a set of mixing subcircuits and, where each mixing subcircuit may output a respective component signal. The satellite transponder may sum the component signals output from the set of mixing subcircuits to obtain the second signal with one or more harmonics of the oscillator frequency suppressed. In some examples, the satellite transponder may adjust a phase of phase shifters within the set of mixing subcircuits, where the one or more harmonics of the oscillator frequency may be suppressed based on the adjusting. The satellite transponder may amplify the second signal at a power amplifier of the satellite transponder.

### BRIEF DESCRIPTION OF THE DRAWINGS

FIG. 1 shows an example of a satellite transponder signal diagram that supports a single down conversion satellite payload with polyphase mixer in accordance with examples described herein.

FIG. 2 shows an example of a satellite transponder that supports a single down conversion satellite payload with polyphase mixer in accordance with examples described herein.

FIG. 3 shows an example of a satellite transponder signal diagram that supports a single down conversion satellite payload with polyphase mixer in accordance with aspects of the present disclosure.

FIGS. 4A, 4B, and 4C show examples of frequency domain responses that support a single down conversion satellite payload with polyphase mixer in accordance with aspects of the present disclosure.

FIG. 5 shows an example of a satellite transponder signal diagram that supports a single down conversion satellite payload with polyphase mixer in accordance with aspects of the present disclosure.

### DETAILED DESCRIPTION

A transponder may be capable of receiving an input radio frequency (RF) signal over a first band spanning a first range of frequencies and emitting an output RF signal over a second band spanning a second range of frequencies. Frequency conversion for the transponder may be performed using indirect conversion where the input RF signal may be mixed with a first oscillator signal to generate an intermediate frequency signal, and then the intermediate frequency signal may be mixed with a second oscillator signal to generate the output RF signal. Frequency conversion for the transponder may also be performed using direct conversion where the input RF signal is mixed with a single oscillator signal generated by a local oscillator to obtain the output RF signal directly without generating the intermediate frequency signal. For indirect conversion, the oscillator signals (e.g., first oscillator signal, second oscillator signal) are generally relatively close to the first band or second band. For example, if the first band is centered around 30 GHz and the second band is centered around 20 GHZ, the first and second oscillator signals may be 28 GHz and 18 GHz, such that the intermediate frequency signal is centered around 2 GHz. In this case, harmonics and mixing products of the oscillator signals and the input RF signal may not generally be within the second band (the band of the output RF signal) such that they cause distortion in the output RF signal. For example, the harmonics of the first, 28 GHz oscillator signal (e.g., 56 GHz, 84 GHZ) may be higher than the second band. For direct conversion, however, it is more likely that harmonics of the oscillator signal and mixing products of the oscillator signal and the input RF signal are within the band of the output RF signal.

Using direct conversion, mixing the input RF signal with the oscillator signal may thus introduce distortions from the oscillator harmonics or mixing products (e.g., due to a non-linearity associated with the mixer performing the mixing). If these mixing products are located outside of the second band, the direct-conversion transponder may suppress these mixing products using a bandpass filter. However, if these mixing products are located within the second band, a bandpass filter may not be sufficient for suppressing the mixing products within the second band without suppressing other portions of the second band (e.g., the output RF signal).

According to aspects described herein, harmonics and/or mixing products for a direct conversion transponder may be suppressed within the second band using a mixing circuit that employs a polyphase mixer for mixing the input RF signal with the oscillator signal. For instance, the mixing circuit may include a splitting circuit configured to divide the input RF signal among a set of mixing subcircuits. Each mixing subcircuit may include a first respective phase shifter configured to output a respective phase-shifted representation of the input RF signal, a second respective phase shifter configured to output a respective phase-shifted representation of the oscillator signal generated by the local oscillator, and a respective mixer configured to mix the respective phase-shifted representations of the input RF signal and the oscillator signal. The signals output by the respective mixer of each mixing subcircuit of the set of mixing subcircuits may be summed by a summing circuit of the mixing circuit and the summed signal may be output as the output RF signal, where the output RF signal may undergo amplification and/or filtering before being emitted. In some examples, the input RF signal may undergo amplification and/or filtering before being divided by the splitting circuit.

The respective first phase shifter of each mixing subcircuit of the set of mixing subcircuits may shift a phase of the first signal by a different amount such that one or more harmonics of an oscillator frequency associated with the local oscillator are suppressed when the summing circuit sums the signals output by the mixers of the set of mixing subcircuits. For instance, if the set of mixing subcircuits includes three mixing subcircuits, the second harmonic and the third harmonic of the oscillator frequency may be suppressed by the summing performed by the summing circuit. If the mixing products within the second band are aligned with a harmonic of the oscillator frequency suppressed by the mixing circuit, then the mixing products may also be suppressed. In this manner, the mixing products within the second band that may impact the output RF signal may be suppressed.

In some examples, the direct-conversion transponder may include a controller configured to send a command to the mixing circuit that indicates for the mixing circuit to adjust respective phases of a first phase shifter or a second phase shifter of a mixing subcircuit of the set of mixing subcircuits. Additionally, in examples in which each mixing subcircuit includes a respective amplitude adjustment circuit (e.g., a circuit configured to adjust an amplitude of the first signal), the controller may be configured to send a second command to the mixing circuit that indicates for the mixing circuit to adjust respective amplitudes of the amplitude adjustment circuit for a mixing subcircuit of the set of mixing subcircuits. Adjusting phases of the first and/or second phase shifters and adjusting amplitudes of amplitude adjustment circuits may enable more effective suppression of the one or more harmonics of the oscillator frequency.

In some examples, a subset of harmonics of the oscillator frequency may not be suppressed by a polyphase mixer that is not double-balanced. For instance, if the mixing circuit has three mixing subcircuits, the second and third harmonics of the third signal may be suppressed, but the fourth harmonic may not be suppressed. To suppress the subset of harmonics, the mixing circuit may be double-balanced, which may be used to suppress any even harmonics (e.g., the fourth harmonic in the case of three mixing subcircuits). For instance, the mixing circuit may include a set of differential mixers that are each coupled with a first splitting circuit and a second splitting circuit, where the first splitting circuit is configured to receive a first input RF signal and the second splitting circuit is configured to receive a second input RF signal, and where the first input RF signal and the second input RF signal are a differential pair of signals. Each differential mixer may output a respective first component signal associated with the first input RF signal to a first summing circuit and a respective second component signal associated with the second input RF signal to a second summing circuit. The first summing circuit may sum the respective first component signals from the set of differential mixers and may output a third signal. Additionally, the second summing circuit may sum the respective second component signals from the set of differential mixers and may output a fourth signal. It should be noted that a phase shifter may be present between each differential mixer and the first splitting circuit and may also be present between each differential mixer and the second splitting circuit. In some examples, suppressing the even harmonics may occur more effectively if balances of the differential mixers are adjusted. Thus, the mixing circuit may include one or more balance adjustment circuits to adjust a balance of the differential mixers.

Aspects of the disclosure are described in the context of satellite transponder signal diagrams and a satellite transponder. Additional aspects of the disclosure are described in the context of frequency domain responses.

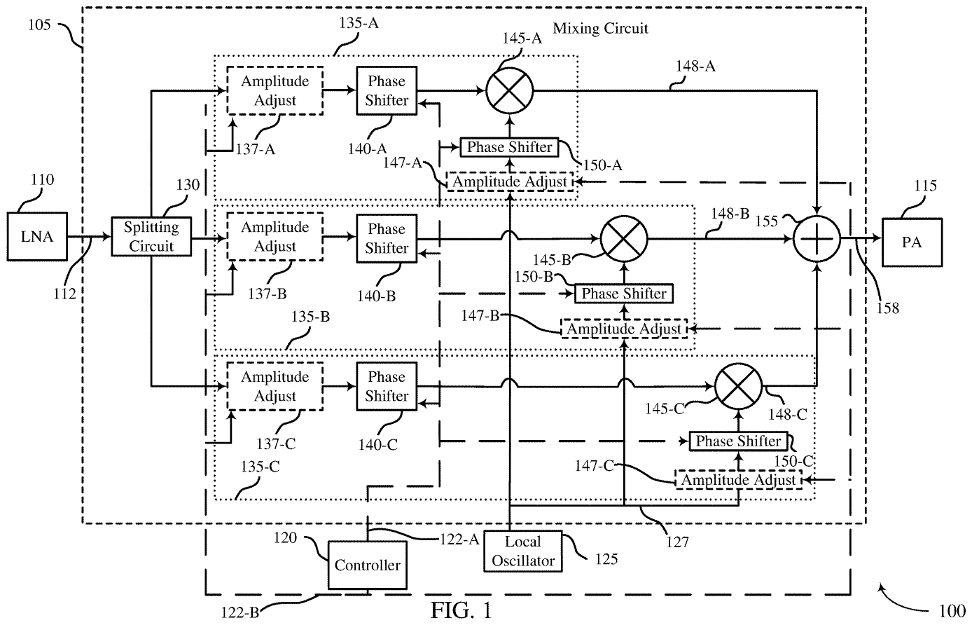

FIG. 1 shows an example of a satellite transponder signal diagram 100 that supports a single down conversion satellite payload with polyphase mixer in accordance with examples described herein.

Satellite transponder signal diagram 100 may include a low noise amplifier (LNA) 110. LNA 110 may be coupled with a mixing circuit 105 and mixing circuit 105 may be coupled with power amplifier (PA) 115, controller 120, and local oscillator 125. Mixing circuit 105 may include a splitting circuit 130 coupled with LNA 110. Additionally, mixing circuit 105 may include a first mixing subcircuit 135-a, a second mixing subcircuit 135-b, and a third mixing subcircuit 135-c each coupled with splitting circuit 130. Mixing circuit 105 may also include a summing circuit 155 coupled with first mixing subcircuit 135-a, second mixing subcircuit 135-b, and third mixing subcircuit 135-c as well as PA 115. In some examples, mixing circuit 105 may be referred to as a polyphase mixer.

First mixing subcircuit 135-a may include first phase shifter 140-a, mixer 145-a, and second phase shifter 150-a; second mixing subcircuit 135-b may include first phase shifter 140-b, mixer 145-b, and second phase shifter 150-b; and third mixing subcircuit 135-c may include first phase shifter 140-c, mixer 145-c, and second phase shifter 150-c. In some examples, first mixing subcircuit 135-a may include amplitude adjustment circuit 137-a, second mixing subcircuit 135-b may include amplitude adjustment circuit 137-b, and third mixing subcircuit 135-c may include amplitude adjustment circuit 137-c. In such examples, amplitude adjustment circuit 137-a may be coupled with splitting circuit 130 and first phase shifter 140-a, amplitude adjustment circuit 137-b may be coupled with splitting circuit 130 and first phase shifter 140-b, and amplitude adjustment circuit 137-c may be coupled with splitting circuit 130 and first phase shifter 140-c. In other examples, first phase shifters 140-a, 140-b, and 140-c may be directly coupled with splitting circuit 130 (e.g., amplitude adjustment circuits 137-a, 137-b, and 137-c may not be present). In some examples, first mixing subcircuit 135-a may include amplitude adjustment circuit 147-a, second mixing subcircuit 135-b may include amplitude adjustment circuit 147-b, and third mixing subcircuit 135-c may include amplitude adjustment circuit 147-c. In such examples, amplitude adjustment circuit 147-a may be coupled with local oscillator 125 and second phase shifter 150-a, amplitude adjustment circuit 147-b may be coupled with local oscillator 125 and second phase shifter 150-b, and amplitude adjustment circuit 147-c may be coupled with local oscillator 125 and second phase shifter 150-c. In other examples, second phase shifters 150-a, 150-b, and 150-c may be directly coupled with local oscillator 125 (e.g., amplitude adjustment circuits 147-a, 147-b, and 147-c may not be present).

First phase shifter 140-a and second phase shifter 150-a may be coupled with mixer 145-a; first phase shifter 140-b and second phase shifter 150-b may be coupled with mixer 145-b; and first phase shifter 140-c and second phase shifter 150-c may be coupled with mixer 145-c. Mixers 145-a, 145-b, and 145-c may be coupled with summing circuit 155. In some examples, one or more of first phase shifters 140-a, 140-b, and 140-c and second phase shifters 150-a, 150-b, and 150-c may be coupled with controller 120. In some examples, amplitude adjustment circuits 137-a, 137-b, and 137-c may be coupled with controller 120.

In some examples, satellite transponder signal diagram 100 may illustrate techniques for suppressing one or more harmonics of an oscillator frequency. For instance, LNA 110 may receive a first signal (e.g., input RF signal) in a first band spanning a first frequency range (e.g., via an antenna). LNA 110 may amplify the first signal and may provide the amplified first signal to mixing circuit 105. Mixing circuit 105 may be configured to frequency convert the first signal to a second signal and to suppress one or more harmonics of the oscillator frequency. For instance, LNA 110 may provide the amplified first signal to splitting circuit 130 and splitting circuit 130 may divide the first signal among first mixing subcircuit 135-a, second mixing subcircuit 135-b, and third mixing subcircuit 135-c. Splitting circuit 130 may provide the first signal to amplitude adjustment circuits 137-a, 137-b, and 137-c or may provide the first signal to first phase shifters 140-a, 140-b, and 140-c (e.g., in examples in which amplitude adjustment circuits 137-a, 137-b, and 137-c are not present). Amplitude adjustment circuits 137-a, 137-b, and 137-c, upon receiving the first signal, may adjust an amplitude of the first signal by a respective amount and may provide the first signal to first phase shifters 140-a, 140-b, and 140-c, respectively. First phase shifters 140-a, 140-b, and 140-c, upon receiving the first signal, may output a respective phase shifted representation of the first signal and may provide the respective phase shifted representation to mixers 145-a, 145-b, and 145-c, respectively.

Additionally, local oscillator 125 may provide an oscillator signal 127 to amplitude adjustment circuits 147-a, 147-b, and 147-c or may provide the oscillator signal 127 to second phase shifters 150-a, 150-b, and 150-c (e.g., in examples in which amplitude adjustments circuits 147-a, 147-b, and 147-c are not present). Amplitude adjustment circuits 147-a, 147-b, and 147-c, upon receiving the oscillator signal 127, may adjust an amplitude of the oscillator signal 127 by a respective amount and may provide the oscillator signal 127 to second phase shifters 150-a, 150-b, and 150-c, respectively. Second phase shifters, upon receiving the oscillator signal 127, may output a respective phase shifted representation of the oscillator signal 127 and may provide the respective phase shifted representation of the oscillator signal 127 to mixers 145-a, 145-b, and 145-c, respectively. It should be noted that the oscillator signal 127 may be split using a splitting circuit as described herein.

Mixer 145-a, upon receiving the respective phase shifted representation of the first signal from first phase shifter 140-a and the respective phase shifted representation of the oscillator signal 127 from second phase shifter 150-a, may mix the respective phase shifted representation of the first signal and the respective phase shifted representation of the oscillator signal and may output a first component signal 148-a. Similarly, mixer 145-b, upon receiving the respective phase shifted representation of the first signal from first phase shifter 140-b and the respective phase shifted representation of the oscillator signal 127 from second phase shifter 150-b, may mix the respective phase shifted representation of the first signal and the respective phase shifted representation of the oscillator signal 127 and may output a second component signal 148-b. Similarly, mixer 145-c, upon receiving the respective phase shifted representation of the first signal from first phase shifter 140-c and the respective phase shifted representation of the oscillator signal 127 from second phase shifter 150-c, may mix the respective phase shifted representation of the first signal and the respective phase shifted representation of the oscillator signal 127 and may output a third component signal 148-c. Mixers 145-a, 145-b, and 145-c may provide the first, second, and third component signals, respectively, to summing circuit 155.

Summing circuit 155 may combine (e.g., sum) the first, second, and third component signals 148-a, 148-b, and 148-c, to obtain the second signal 158 in a second band spanning a second frequency range and may provide the second signal 158 to PA 115. PA 115 may amplify the second signal 158 and may output the amplified second signal (e.g., to an antenna). In some examples, the oscillator frequency of the oscillator signal 127 output by local oscillator 125 may correspond to (e.g., be equal to) a difference between a lowest frequency of the second frequency range of the second band and a lowest frequency of the first frequency range of the first band. Additionally, the frequency-converting performed by mixing circuit 105 may convert the first signal 112 associated with the first range to the second signal 158 associated with the second frequency range.

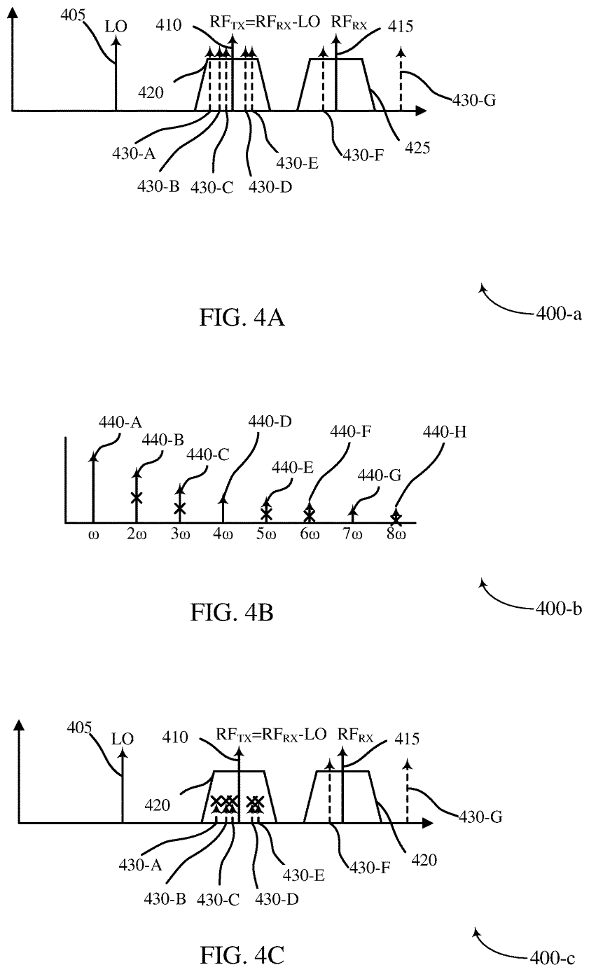

In order to suppress harmonics of the oscillator frequency, first phase shifters 140-a, 140-b, and 140-c and second phase shifters 150-a, 150-b, and 150-c may be configured to shift the phase of the first signal 112 and the oscillator signal 127, respectively, such that the resulting component signals 148-a, 148-b, and 148-c cancel with each other at certain harmonics (e.g., the second harmonic, the third harmonic) and mixing products and not at others (e.g., the fundamental harmonic). For instance, the amount phase is shifted by first phase shifters 140-a, 140-b, and 140-c may be spread out uniformly (e.g., 0 degrees, 120 degrees, and 240 degrees, respectively) and the amount of phase shift of second phase shifters 150-a, 150-b, and 150-c may be spread out uniformly (e.g., 0 degrees, −120 degrees, and −240 degrees, respectively). Additionally, each second phase shifter of a mixing subcircuit may adjust phase by a negative amount of the corresponding first phase shifter for that mixing subcircuit. For instance, if first phase shifter 140-a adjusts the phase of the first signal by 0 degrees, second phase shifter 150-a may adjust the phase of the oscillator signal by −0 degrees. Additionally, if first phase shifter 140-b adjusts the phase of the first signal by 120 degrees, second phase shifter 150-b may adjust the phase of the oscillator signal by −120 degrees. Additional details illustrating the suppression of harmonics of the oscillator frequency and mixing products is described herein, for instance, with reference to FIGS. 4A, 4B, and 4C.

In some examples, having first phase shifters 140-a, 140-b, and 140-c and/or second phase shifters 150-a, 150-b, and 150-c be spread out uniformly in the amount of phase they adjust or having second phase shifters adjust phase by a negative amount of the corresponding first phase shifters may not suppress harmonics optimally (e.g., due to nonlinearities or physical properties associated with the mixing circuit 105). To enable greater suppression of harmonics, a controller 120 may adjust the amount that first phase shifters 140-a, 140-b, and 140-c and/or second phase shifters 150-a, 150-b, and 150-c adjust phase. For instance, controller 120 may send a command 122-a to mixing circuit 105 indicating for mixing circuit 105 to adjust respective phases of at least one of first phase shifters 140-a, 140-b, and 140-c and/or second phase shifters 150-a, 150-b, and 150-c. Additionally, the controller 120 may adjust the amount by which amplitude adjustment circuits 137-a, 137-b, and 137-c and/or amplitude adjustment circuits 147-a, 147-b, and 147-c adjust amplitude. For instance, controller 120 may send a second command 122-b to mixing circuit 105 that indicates for mixing circuit 105 to adjust respective amplitudes of at least one of amplitude adjustment circuits 137-a, 137-b, 137-c, 147-a, 147-b, and 147-c. In some examples, how much first phase shifters 140-a, 140-b, and 140-c, second phase shifters 150-a, 150-b, and 150-c, and/or amplitude adjustment circuits 137-a, 137-b, 137-c, 147-a, 147-b, and 147-c are adjusted may be dependent on a temperature associated with the satellite transponder (e.g., a temperature of the transponder).

In some examples, the techniques described herein may be associated with one or more advantages. For instance, suppressing mixing products may reduce an amount of distortion within a band of a signal transmitted from the transponder. Reducing the amount of distortion may increase a likelihood that a receiving device successfully decodes the signal. The techniques described herein may have advantages over global feedback mitigation techniques (e.g., usage of operation amplifiers), which may lack sufficient loop gain at gigahertz (GHz) bands. Additionally, or alternatively, the techniques described herein may have advantages over filtering mitigation techniques (e.g., use of a filter to suppress harmonics) as the roll-off may be limited and in-band spurs may be difficult to suppress.

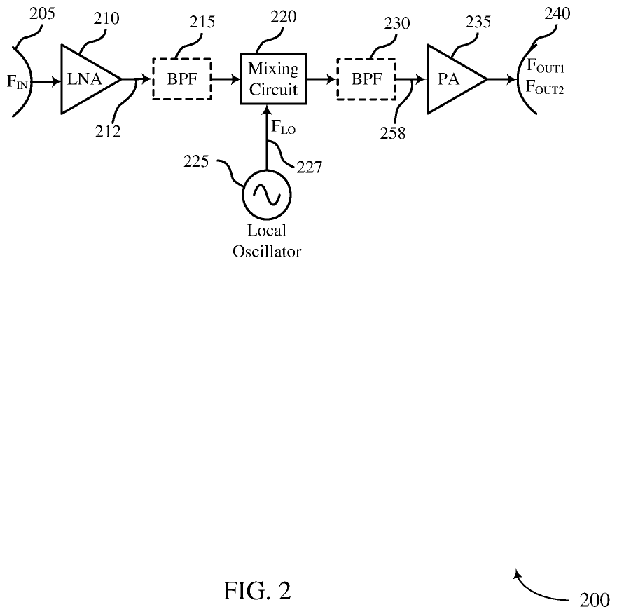

FIG. 2 shows an example of satellite transponder 200 (e.g., a single frequency conversion transponder with a polyphase mixer) that supports a single down conversion satellite payload with polyphase mixer in accordance with aspects of the present disclosure. In some examples, satellite transponder 200 may include one or more aspects of satellite transponder signal diagram 100. For instance, LNA 210 may be an example of an LNA 110 as described with reference to FIG. 1; mixing circuit 220 may be an example of a mixing circuit 105 as described with reference to FIG. 1; PA 235 may be an example of a PA 115 as described with reference to FIG. 1; local oscillator 225 may be an example of a local oscillator 125 as described with reference to FIG. 1; or any combination thereof.

Antenna 205 may be coupled with LNA 210. Antenna 205 may be, for example, a phased array antenna, a direct-radiating phased array antenna, a phased array fed reflector (PAFR) antenna, or any other type of antenna known in the art for transmission and/or reception of signals. LNA 210 may be coupled with bandpass filter 215 or may be directly coupled with mixing circuit 220 (e.g., if bandpass filter 215 is not present). Mixing circuit 220 may be coupled with local oscillator 225 and bandpass filter 230. In some examples, mixing circuit 220 may be couple directly with PA 235 (e.g., if bandpass filter 230 is not present). PA 235 may be coupled directly with antenna 240. In some cases, antenna 205, LNA 210, and bandpass filter 215 may be part of an antenna system, which may include a beamformer (e.g., an analog beamformer).

In some examples, satellite transponder 200 may illustrate techniques for frequency conversion in which one or more oscillator harmonics are suppressed. For instance, antenna 205 may receive a first signal (e.g., a first signal with frequency F_{IN}) in a first band and may provide the first signal to LNA 210. LNA 210 may amplify the first signal and may provide the first signal 212 to bandpass filter 215 or mixing circuit 220 (e.g., if bandpass filter 215 is not present). Bandpass filter 215 may filter the first signal 212 to be within the first band and may provide the first signal 212 to mixing circuit 220.

Mixing circuit 220 may frequency-convert the first signal 212 in the first band to a second signal 258 in a second band using an oscillator signal 227 from the local oscillator 225, where mixing products formed via the mixing process may be suppressed using a polyphase mixer. For instance, the mixing products may be aligned with (e.g., at a same frequency as) one or more suppressed harmonics of an oscillator frequency of the oscillator signal output by local oscillator 225 and may thus be suppressed in a similar fashion as the one or more suppressed harmonics are suppressed.

The mixing circuit 220 may provide the second signal to bandpass filter 230 or may provide the second signal to PA 235 (e.g., in examples in which bandpass filter 230 is not present). Bandpass filter 230 may filter the second signal to be within the second band and may provide the second signal to PA 235. PA 235 may amplify the second signal and may provide the second signal to antenna 240. Antenna 240 may transmit the second signal (e.g., at a frequency F_{OUT1} or a frequency F_{OUT2}, where F_{OUT1}=F_{IN}−F_{LO} and F_{OUT2}=F_{IN}+F_{LO}). Antenna 240 may be, for example, a phased array antenna, a direct-radiating phased array antenna, a PAFR antenna, or any other type of antenna known in the art for transmission and/or reception of signals. In some cases, antenna 240, PA 235, and bandpass filter 230 may be part of an antenna system, which may include a beamformer (e.g., an analog beamformer).

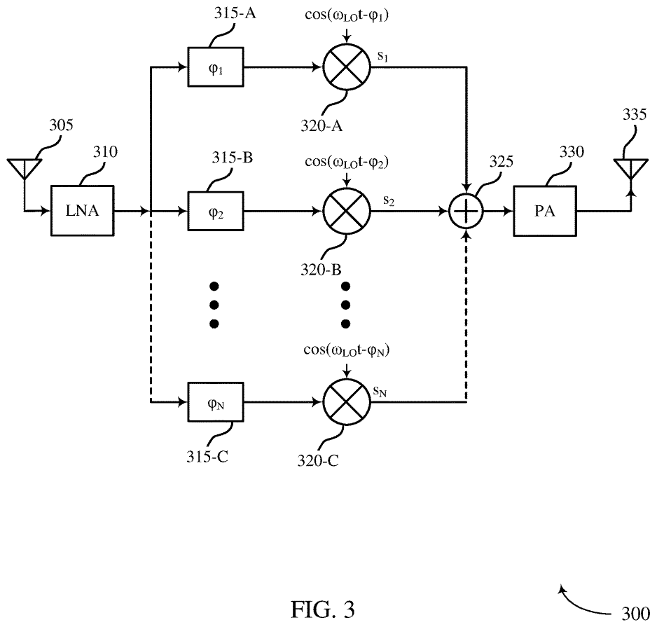

FIG. 3 shows an example of a satellite transponder signal diagram 300 that supports a single down conversion satellite payload with polyphase mixer in accordance with aspects of the present disclosure. In some examples, satellite transponder signal diagram 300 may implement one or more aspects of satellite transponder signal diagram 100 and/or satellite transponder 200. For instance, antenna 305 may be an example of an antenna 205 as described with reference to FIG. 2; LNA 310 may be an example of an LNA 110 as described with reference to FIG. 1 and/or an LNA 210 as described with reference to FIG. 2; first phase shifters 315-a, 315-b, and 315-c may be each be an example of any of first phase shifters 140-a, 140-b, and 140-c as described with reference to FIG. 1; mixers 320-a, 320-b, and 320-c may each be an example of any of mixers 145-a, 145-b, and 145-c as described with reference to FIG. 1; summing circuit 325 may be an example of a summing circuit 155 as described with reference to FIG. 1; PA 330 may be an example of a PA 115 as described with reference to FIG. 1 or a PA 235 as described with reference to FIG. 2; antenna 335 may be an example of antenna 240 as described with reference to FIG. 2; or any combination thereof.

Antenna 305 may be coupled with LNA 310 and LNA 310 may be coupled with each of first phase shifters 315-a, 315-b, and 315-c. First phase shifter 315-a may be coupled with mixer 320-a, first phase shifter 315-b may be coupled with mixer 320-b, and first phase shifter 315-c may be coupled with mixer 320-c. Mixers 320-a, 320-b, and 320-c may be coupled with summing circuit 325. Summing circuit 325 may be coupled with PA 330 and PA 330 may be coupled with antenna 335.

In some examples, satellite transponder signal diagram 300 may illustrate techniques for frequency conversion in which one or more oscillator harmonics are suppressed. For instance, antenna 305 may receive a first signal in a first band and may provide the first signal to LNA 310. LNA 310 may amplify the first signal and may provide the first signal to a set of first phase shifters (e.g., a set including first phase shifters 315-a, 315-b, and 315-c, where there are N first phase shifters in total). First phase shifter 315-a may shift the first signal by φ₁, first phase shifter 315-b may shift the first signal by φ₂, and first phase shifter 315-c may shift the first signal by φ_{N}. First phase shifter 315-a may provide the first signal phase shifted by φ₁ to mixer 320-a, first phase shifter 315-b may provide the first signal phase shifted by φ₂ to mixer 320-b, and first phase shifter 315-c may provide the first signal phase shifted by ON to mixer 320-c. Mixer 320-a may mix the first signal phase shifted by φ₁ with signal cos (ω_{LO}t−φ₁), where ω_{Lo} may correspond to an oscillator frequency of a local oscillator and t may represent a time variable. Mixer 320-b may mix the first signal phase shifted by φ₂ with signal cos (ω_{LO}t−φ₂) and mixer 320-c may mix the first signal phase shifted by φ_{N} with signal cos (ω_{LO}t−φ_{N}). After performing the mixing, mixer 320-a may output a first component signal (e.g., component signal s₁), mixer 320-b may output a second component signal (e.g., component signal s₂), and mixer 320-c may output an Nth component signal (e.g., component signal s_{N}). The first component signal, the second component signal, and the Nth component signal may be provided to summing circuit 325 and summing circuit 325 may sum the first component signal, the second component signal, and the Nth component signal. In total, N component signals may be generated from N mixers and the N component signals may be summed at summing circuit 325. Summing each of the N component signals may enable summing circuit 325 to obtain the second signal in a second band. The second signal may be provided by summing circuit 325 to PA 330 and PA 330 may amplify the second signal. PA 330 may provide the amplified second signal to antenna 335. Antenna 335 may transmit the amplified second signal.

In some examples (e.g., for frequency translation), mixers 320-a, 320-b, and 320-c may be configured to perform down-conversion and phase-shifting functions and may be examples of analog mixers. Using mixers 320-a, 320-b, and 320-c to perform phase-shifting functions may enable a wider band to be used than if phase shifters were used for this purpose. In some examples, mixers 320-a, 320-b, and 320-c may be modeled as non-linear circuits.

FIGS. 4A, 4B, and 4C show examples of frequency domain responses 400-a, 400-b, and 400-c that support a single down conversion satellite payload with polyphase mixer in accordance with aspects of the present disclosure. In some examples, one or more aspects of FIGS. 4A, 4B, and 4C may represent signals associated with one or more aspects of satellite transponder signal diagram 100 and/or 300 or satellite transponder 200. For instance, local oscillator frequency 405 may correspond to a frequency of a signal output by local oscillator 125 of FIG. 1 or a signal output by local oscillator 225 of FIG. 2. Additionally, or alternatively, transmit frequency 410 may represent a frequency of, and transmit frequency profile 420 may represent a band of, a signal produced by mixing circuit 105 of FIG. 1, a signal produced by mixing circuit 220 of FIG. 2, and/or a signal produced by summing circuit 325 of FIG. 3. Additionally, or alternatively, receive frequency 415 may represent a frequency of, and receive frequency profile 425 may represent a band of, a signal received by mixing circuit 105 of FIG. 1, a signal received by mixing circuit 220 of FIG. 2, and/or a signal output by LNA 310 of FIG. 3.

As depicted in FIG. 4A, a signal provided from an LNA may have a receive frequency 415 (e.g., a center frequency RF_{RX}) and may have a receive frequency profile 425 within a first frequency range, Additionally, a signal provided by a local oscillator may have an oscillator frequency 405 (e.g., oscillator frequency LO). After the signal provided from the LNA and the signal provided by the local oscillator are input to a single-phase mixer, a second signal may be generated by the single-phase mixer that may have a transmit frequency 410 (e.g., a center frequency RF_{TX}) and a transmit frequency profile 420 associated with a second frequency range. In some examples, the transmit frequency 410 may be dependent on the receive frequency 415 and the oscillator frequency 405 (e.g., RF_{TX}=RF_{RX}−LO).

In some examples, a single-phase mixer mixing the signal provided from the LNA and the signal provided from the local oscillator may generate one or more mixing products. For instance, mixing products 430-a, 430-b, 430-c, 430-d, 430-e, 430-f, and 430-g may be generated. Some of the mixing products may be outside of the second frequency range associated with transmit frequency profile 420. For instance, mixing products 430-f and 430-g may be outside of the second frequency range. Thus, a bandpass filter may be used to filter out mixing products 430-f and 430-g without affecting the transmit frequency profile 420. In some examples for using direct downconversion, LO may be less than half of RF_{RX}, such that RF_{TX}>LO. For example, RF_{RX} may be approximately 30 GHz and LO may be approximately 10 GHz. However, mixing products 430-a, 430-b, 430-c, 430-d, and 430-e may be inside of the second frequency range. In such examples, using a bandpass filter to filter out these mixing products may affect the transmit frequency profile 420 since there is overlap between frequencies of the transmit frequency profile 420 and these mixing products.

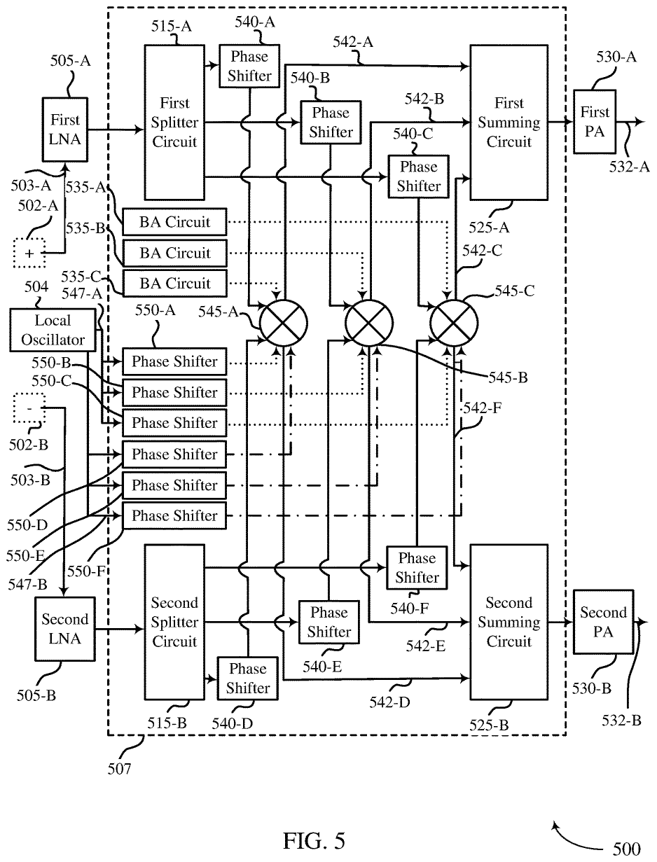

Using a polyphase mixer as described herein may enable suppression or cancellation of one or more harmonics of the oscillator frequency 405. For instance, as depicted in FIG. 4B, the polyphase mixer may not suppress a first harmonic 440-a (e.g., a fundamental harmonic ω) of the oscillator frequency 405, but may suppress a second harmonic 440-b (e.g., 2*w), a third harmonic 440-c (e.g., 3*w), a fifth harmonic 440-e (e.g., 5*w), a sixth harmonic 440-f (e.g., 6*w), and an eighth harmonic 440-h (e.g., 8*w) of oscillator frequency 405. Additionally, the polyphase mixer may not suppress fourth harmonic 440-d (e.g., 4*w) or seventh harmonic 440-g (e.g., 7*w). However, a double-balanced mixer as described herein (e.g., with regards to FIG. 5) may be used to suppress even harmonics, including fourth harmonic 440-d.

In some examples, mixing products 430-a, 430-b, 430-c, 430-d, and 430-e may overlap or align with at least one of second harmonic 440-b, third harmonic 440-c, fifth harmonic 440-e, sixth harmonic 440-f, or eighth harmonic 440-h (e.g., or fourth harmonic 440-d if the polyphase mixer is double-balanced). Thus, using the same mechanism that suppresses the harmonics of the oscillator frequency 405, the mixing products may also be suppressed or cancelled, as depicted in FIG. 4C. Examples of the frequencies to which each of mixing products 430-a, 430-b, 430-c, 430-d, and 430-e corresponds may include 3RF-7LO, 2LO, 5LO-RF, 2RF-4LO, where RF may be equivalent to RF_{RX}. In some examples, the value of RF may be approximately a multiple of LO (e.g., RF~2LO, 3LO, etc.).

An example of mixing products and whether they are cancelled out by the techniques described herein may be depicted in Table 1.

TABLE 1
Mixing Product Cancellations (<50 GHz)

| | | | Canceled By |
|---|---|---|---|
| | | Canceled By | Three-Path |
| Mixing Product | Frequency (GHz) | Single Mixer | Polyphase Mixer |
| RF − LO | 19.2 | No | No |
| 2LO | 19.6 | No | Yes |
| 5LO − RF | 20.0 | No | Yes |
| 3RF − 7LO | 18.4 | No | Yes |
| 2RF − 4LO | 18.8 | No | Yes |
| 8LO − 2RF | 20.4 | No | No |
| RF + LO | 38.8 | No | Yes |
| 3RF − 5LO | 38.0 | No | Yes |
| 7LO − RF | 39.6 | No | No |
| 2RF − 2LO = | 38.4 | No | No |
| 2*(RF − LO) | | | |
| 4RF − 8LO | 37.6 | No | Yes |
| 4LO | 39.2 | No | Yes |
| 3LO − RF | 0.4 | No | Yes |
| 6LO − 2RF | 0.8 | No | Yes |
| 9LO − 3RF | 1.2 | No | No |

In some examples, RF-LO as entered in Table 1 may correspond to transmit frequency 410. Additionally, mixing products 2LO, 5LO-RF, 3RF-LO, 2RF-LO, and 8LO-2RF as entered in Table 1 may correspond to mixing products within transmit frequency profile 420 (e.g., in-band mixing products). The mixing products 2LO, 5LO-RF, 3RF-LO, and 2RF-LO may be cancelled out according to the techniques described herein and may thus correspond to any of mixing products 430-a, 430-b, 430-c, 430-d, and 430-e. Mixing products RF+LO, 3RF-5LO, 7LO-RF, 2RF-2LO, 4RF-8LO, 4LO, 3LO-RF, 6LO-2RF, and 9LO-3RF may be examples of mixing products outside of transmit frequency profile 420 (e.g., out-of-band mixing products). Some of these out-of-band mixing products may be cancelled out according to the techniques described herein (e.g., RF+LO, 3RF-5LO, 4RF-8LO, 4LO, 3LO-RF). For Table 1, the value of LO may be equal to 9.8 GHz and the value of RF may be equal to 29 GHz

It should be noted that Table 1 is for illustrative purposes and that other values of RF and LO are possible which may provide for different mixing products being in-band or out-of-band.

FIG. 5 shows an example of a satellite transponder signal diagram 500 that supports a single down conversion satellite payload with polyphase mixer in accordance with aspects of the present disclosure. In some examples, satellite transponder signal diagram 500 may represent one or more aspects of satellite transponder signal diagrams 100 and/or 300 or satellite transponder 200. For instance, first LNA 505-a and second LNA 505-b may each be an example of an LNA 110 as described with reference to FIG. 1, an LNA 210 as described with reference to FIG. 2, and/or an LNA 310 as described with reference to FIG. 3; mixing circuit 507 may an example of a mixing circuit 105 as described with reference to FIG. 1 and/or a mixing circuit 220 as described with reference to FIG. 2; first splitter circuit 515-a and second splitter circuit 515-b may each be an example of a splitting circuit 130 as described with reference to FIG. 1; any of first phase shifters 540-a, 540-b, 540-c, 540-d, 540-e, and 540-f may be an example of a first phase shifter 140-a, 140-b, or 140-c as described with reference to FIG. 1 and/or any of first phase shifters 315-a, 315-b, and 315-c as described with reference to FIG. 3; any of differential mixers 545-a, 545-b, and 545-c may be an example of a mixer 145-a, 145-b, or 145-c as described with reference to FIG. 1 and/or any of mixers 320-a, 320-b, and 320-c as described with reference to FIG. 3; any of second phase shifters 550-a, 550-b, 550-c, 550-d, 550-e, and 550-f may be an example of a second phase shifter 150-a, 150-b, or 150-c as described with reference to FIG. 1; local oscillator 504 may be an example of a local oscillator 125 as described with reference to FIG. 1; first summing circuit 525-a and second summing circuit 525-b may each be an example of a summing circuit 155 as described with reference to FIG. 1 and/or a summing circuit 325 as described with reference to FIG. 3; first PA 530-a and second PA 530-b may each be an example of a PA 115 as described with reference to FIG. 1, a PA 235 as described with reference to FIG. 2, and/or a PA 330 as described with reference to FIG. 3; or any combination thereof.

First LNA 505-a may be coupled with a first differential port 502-a and mixing circuit 507. Mixing circuit 507 may include a first splitter circuit 515-a coupled with first LNA 505-a and first phase shifter 540-a, first phase shifter 540-b, and first phase shifter 540-c. First phase shifter 540-a may be coupled with first differential mixer 545-a, first phase shifter 540-b may be coupled with second differential mixer 545-b, and first phase shifter 540-c may be coupled with third differential mixer 545-c. Differential mixers 545-a, 545-b, and 545-c may be coupled with first summing circuit 525-a of mixing circuit 507. First summing circuit 525-a may be coupled with first PA 530-a.

Second LNA 505-b may be coupled with a second differential port 502-b and mixing circuit 507. Mixing circuit 507 may include a second splitter circuit 515-b coupled with second LNA 505-b and first phase shifter 540-d, first phase shifter 540-e, and first phase shifter 540-f. First phase shifter 540-d may be coupled with first differential mixer 545-a, first phase shifter 540-e may be coupled with second differential mixer 545-b, and first phase shifter 540-f may be coupled with third differential mixer 545-c. Differential mixers 545-a, 545-b, and 545-c may be coupled with second summing circuit 525-b of mixing circuit 507. Second summing circuit 525-b may be coupled with second PA 530-b.

Mixing circuit 507 may include one or more balance adjustment circuits. For instance, mixing circuit 507 may include first balance adjustment circuit 535-a, second balance adjustment circuit 535-b, and third balance adjustment circuit 535-c. First balance adjustment circuit 535-a may be coupled with first differential mixer 545-a; second balance adjustment circuit 535-b may be coupled with second differential mixer 545-b; and third balance adjustment circuit 535-c may be coupled with third differential mixer 545-c.

Mixing circuit 507 may include one or more second phase shifters. For instance, mixing circuit 507 may include second phase shifter 550-a, second phase shifter 550-b, and second phase shifter 550-c, second phase shifter 550-d, second phase shifter 550-e, and second phase shifter 550-f. Second phase shifter 550-a and second phase shifter 550-d may be coupled with first differential mixer 545-a; second phase shifter 550-b and second phase shifter 550-e may be coupled with second differential mixer 545-b; and second phase shifter 550-c and second phase shifter 550-f may be coupled with third differential mixer 545-c. Each of second phase shifters 550-a, 550-b, 550-c, 550-d, 550-e, and 550-f may be coupled with local oscillator 504.

In some examples, satellite transponder signal diagram 500 may illustrate techniques for suppressing even harmonics of an oscillator frequency by using a double-balanced polyphase mixer. For instance, first LNA 505-a may receive a first signal 503-a from differential port 502-a and second LNA 505-b may receive a second signal 503-b from differential port 502-b. The first signal 503-a and the second signal 503-b may be a differential pair of signals.

Local oscillator 504 may generate a first oscillator signal 547-a and may provide the first oscillator signal 547-a to second phase shifters 550-a, 550-b, and 550-c. Additionally, local oscillator 504 may generate a second oscillator signal 547-b and may provide the second oscillator signal 547-b to second phase shifters 550-d, 550-e, and 550-f. Second phase shifter 550-a may provide a first phase shifted representation of the first oscillator signal 547-a to first differential mixer 545-a, second phase shifter 550-b may provide a second phase shifted representation of the first oscillator signal 547-a to second differential mixer 545-b, and second phase shifter 550-c may provide a third phase shifted representation of the first oscillator signal 547-a to third differential mixer 545-c. Second phase shifter 550-d may provide a first phase shifted representation of the second oscillator signal 547-b to first differential mixer 545-a, second phase shifter 550-e may provide a second phase shifted representation of the second oscillator signal 547-b to second differential mixer 545-b, and second phase shifter 550-f may provide a third phase shifted representation of the second oscillator signal 547-b to third differential mixer 545-c. The first oscillator signal 547-a and second oscillator signal 547-b may be a differential pair of signals.

First LNA 505-a may amplify the first signal 503-a and may provide the first signal 503-a to first splitter circuit 515-a of mixing circuit 507. First splitter circuit 515-a may split the first signal 503-a among first phase shifters 540-a, 540-b, and 540-c. First phase shifter 540-a may provide a first phase shifted representation of first signal 503-a to first differential mixer 545-a, first phase shifter 540-b may provide a second phase shifted representation of first signal 503-a to second differential mixer 545-b; and first phase shifter 540-c may provide a third phase shifted representation of first signal 503-a to third differential mixer 545-c.

Second LNA 505-b may amplify the second signal 503-b and may provide the second signal 503-b to second splitter circuit 515-b of mixing circuit 507. Second splitter circuit 515-b may split the second signal 503-b among first phase shifters 540-d, 540-e, and 540-f. First phase shifter 540-d may provide a first phase shifted representation of second signal 503-b to first differential mixer 545-a; first phase shifter 540-e may provide a first phase shifted representation of second signal 503-b to second differential mixer 545-b; and first phase shifter 540-f may provide a third phase shifted representation of second signal 503-b to third differential mixer 545-c.

First differential mixer 545-a may output first component signal 542-a to first summing circuit 525-a and may output fourth component signal 542-d to second summing circuit 525-b. Second differential mixer 545-b may output second component signal 542-b to first summing circuit 525-a and may output fifth component signal 542-e to second summing circuit 525-b. Third differential mixer 545-c may output third component signal 542-c to first summing circuit 525-a and may output sixth component signal 542-f to second summing circuit 525-b. Each of first component signal 542-a, second component signal 542-b, and third component signal 542-c may be associated with first signal 503-a (e.g., associated with mixing respective phase shifted representations of first signal 503-a and respective phase shifted representations of the first oscillator signal 547-a). Each of fourth component signal 542-d, fifth component signal 542-e, and sixth component signal 542-f may be associated with second signal 503-b (e.g., associated with mixing respective phase shifted representations of second signal 503-b (e.g., associated with mixing respective phase shifted representations of second signal 503-b and respective phase shifted representations of the second oscillator signal 547-b.

First summing circuit 525-a may sum the first component signal 542-a, the second component signal 542-b, and the third component signal 542-c to generate third signal 532-a and may provide third signal 532-a to first PA 530-a. First PA 530-a may amplify third signal 532-a and may output the amplified third signal 532-a. Second summing circuit 525-b may sum the fourth component signal 542-d, the fifth component signal 542-e, and the sixth component signal 542-f to generate fourth signal 532-b and may provide fourth signal 532-b to second PA 530-b. Second PA 530-b may amplify fourth signal 532-b and may output the amplified fourth signal 532-b.

In some examples, the suppression of even harmonics may occur due to first signal 503-a and second signal 503-b being a differential pair. In some examples, adjusting a balance of differential mixers may more effectively suppress even harmonics of an oscillator frequency. For instance, first balance adjustment circuit 535-a may adjust or calibrate a balance of first differential mixer 545-a; second balance adjustment circuit 535-b may adjust or calibrate a balance of second differential mixer 545-b; and third balance adjustment circuit 535-c may adjust or calibrate a balance of third differential mixer 545-c.

In some examples, an apparatus as described herein may perform a method or methods. The apparatus may include features, circuitry, logic, means, or instructions (e.g., a non-transitory computer-readable medium storing instructions executable by a processor), or any combination thereof for performing the following aspects of the present disclosure:

It should be noted that these methods describe examples of implementations, and that the operations and the steps may be rearranged or otherwise modified such that other implementations are possible. In some examples, aspects from two or more of the methods may be combined. For example, aspects of each of the methods may include steps or aspects of the other methods, or other steps or techniques described herein.

Information and signals described herein may be represented using any of a variety of different technologies and techniques. For example, data, instructions, commands, information, signals, bits, symbols, and chips that may be referenced throughout the description may be represented by voltages, currents, electromagnetic waves, magnetic fields or particles, optical fields or particles, or any combination thereof.

The various illustrative blocks and modules described in connection with the disclosure herein may be implemented or performed with a general purpose processor, a DSP, an ASIC, an FPGA, or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices (e.g., a combination of a DSP and a microprocessor, multiple microprocessors, one or more microprocessors in conjunction with a DSP core, or any other such configuration).

The functions described herein may be implemented in hardware, software executed by a processor, firmware, or any combination thereof. If implemented in software executed by a processor, the functions may be stored on or transmitted over as one or more instructions or code on a computer readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

Computer readable media includes both non transitory computer storage media and communication media including any medium that facilitates transfer of a computer program from one place to another. A non-transitory storage medium may be any available medium that can be accessed by a general purpose or special purpose computer. By way of example, and not limitation, non-transitory computer readable media may include RAM, ROM, electrically erasable programmable read-only memory (EEPROM), flash memory, compact disk read-only memory (CDROM) or other optical disk storage, magnetic disk storage or other magnetic storage devices, or any other non-transitory medium that can be used to carry or store desired program code means in the form of instructions or data structures and that can be accessed by a general purpose or special purpose computer, or a general purpose or special purpose processor. Also, any connection is properly termed a computer readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk and Blu ray disc where disks usually reproduce data magnetically, while discs reproduce data optically with lasers. Combinations of the above are also included within the scope of computer readable media.

As used herein, including in the claims, “or” as used in a list of items (e.g., a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label, or other subsequent reference label.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, well known structures and devices are shown in block diagram form in order to avoid obscuring the concepts of the described examples.

The description herein is provided to enable a person skilled in the art to make or use the disclosure. Various modifications to the disclosure will be readily apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

1. A satellite transponder, comprising:
a low noise amplifier configured to amplify a first signal;
a local oscillator configured to generate an oscillator signal at an oscillator frequency;
a mixing circuit coupled with the low noise amplifier and the local oscillator, wherein the mixing circuit is configured to frequency convert the first signal to a second signal and to suppress one or more harmonics of the oscillator frequency, wherein the mixing circuit comprises:
a splitter circuit coupled with the low noise amplifier and configured to divide the first signal among a first mixing subcircuit, a second mixing subcircuit, and a third mixing subcircuit;
the first mixing subcircuit comprising a respective first phase shifter configured to receive the first signal from the splitter circuit and to output a first phase shifted representation of the first signal, a respective second phase shifter configured to receive the oscillator signal and to output a first phase shifted representation of the oscillator signal, and a first mixer configured to receive the first phase shifted representation of the first signal and the first phase shifted representation of the oscillator signal and to output a first component signal;
the second mixing subcircuit comprising a respective first phase shifter configured to receive the first signal from the splitter circuit and to output a second phase shifted representation of the first signal, a respective second phase shifter configured to receive the oscillator signal and to output a second phase shifted representation of the oscillator signal, and a second mixer configured to receive the second phase shifted representation of the first signal and the second phase shifted representation of the oscillator signal and to output a second component signal;
the third mixing subcircuit comprising a respective first phase shifter configured to receive the first signal from the splitter circuit and to output a third phase shifted representation of the first signal, a respective second phase shifter configured to receive the oscillator signal and to output a third phase shifted representation of the oscillator signal, and a third mixer configured to receive the third phase shifted representation of the first signal and the third phase shifted representation of the oscillator signal and to output a third component signal; and
a summing circuit configured to sum the first component signal, the second component signal, and the third component signal to obtain the second signal;
a power amplifier coupled with the mixing circuit and configured to amplify the second signal; and
a controller coupled with the mixing circuit, wherein the controller is configured to:
send a command to the mixing circuit that indicates for the mixing circuit to adjust respective phases of at least one of the first or second phase shifters of at least one of the first, second, or third mixing subcircuits, and wherein the adjustment of the respective phases is configured to suppress the one or more harmonics of the oscillator frequency.

2. The satellite transponder of claim 1, further comprising:
a second low noise amplifier coupled with the mixing circuit and configured to amplify a third signal, wherein the first signal and the third signal are differential pairs of signals, and wherein the mixing circuit further comprises:
a second splitter circuit coupled with the second low noise amplifier and configured to divide the third signal among the first mixer, the second mixer, and the third mixer, wherein each of the first mixer, the second mixer, and the third mixer is a differential mixer, wherein the first mixer is configured to output a fourth component signal based at least in part on the third signal, the second mixer is configured to output a fifth component signal based at least in part on the third signal, and the third mixer is configured to output a sixth component signal based at least in part on the third signal;
a second summing circuit configured to sum the fourth component signal, the fifth component signal, and the sixth component signal to obtain a fourth signal; and
a second power amplifier coupled with the mixing circuit and configured to amplify the fourth signal.

3. The satellite transponder of claim 2, further comprising:
a first balance adjustment circuit coupled with the first mixer;
a second balance adjustment circuit coupled with the second mixer; and
a third balance adjustment circuit coupled with the third mixer,
wherein the controller is further configured to adjust the first balance adjustment circuit to adjust a balance of the first mixer, to adjust the second balance adjustment circuit to adjust a balance of the second mixer, and to adjust the third balance adjustment circuit to adjust a balance of the third mixer.

4. The satellite transponder of claim 1, wherein the mixing circuit further comprises:
a first amplitude adjustment circuit of the first mixing subcircuit;
a second amplitude adjustment circuit of the second mixing subcircuit;
a third amplitude adjustment circuit of the third mixing subcircuit,
wherein the controller is further configured to send a second command to the mixing circuit that indicates for the mixing circuit to adjust respective amplitudes of at least one of the first amplitude adjustment circuit, the second amplitude adjustment circuit, or the third amplitude adjustment circuit, wherein the adjustment of the respective amplitudes is configured to suppress the one or more harmonics of the oscillator frequency.

5. The satellite transponder of claim 4, wherein
the respective amplitude for the first amplitude adjustment circuit, the second amplitude adjustment circuit, and the third amplitude adjustment circuit is the same prior to the adjusting, and
the respective amplitude for a first of the first amplitude adjustment circuit, the second amplitude adjustment circuit, or the third amplitude adjustment circuit is different from the respective amplitude for a second of the first amplitude adjustment circuit, the second amplitude adjustment circuit, or the third amplitude adjustment circuit after the adjusting.

6. The satellite transponder of claim 1, wherein respective amounts by which the respective phases of the at least one of the first or second phase shifters of the at least one of the first, second, or third mixing subcircuits are adjusted is based at least in part on a temperature of the satellite transponder.

7. The satellite transponder of claim 1, wherein
the first phase shifters of the first, second, and third mixing subcircuits have an order,
the respective phase for each phase shifter of the first phase shifters is offset from a respective phase of a respective adjacent phase shifter of the first phase shifters in the order by a same amount prior to the adjusting, and
the respective phase for a phase shifter of the first phase shifters is offset from the respective phase of the respective adjacent phase shifter by a different amount after the adjusting.

8. The satellite transponder of claim 1, wherein
the second phase shifters of the first, second, and third mixing subcircuits have an order,
the respective phase for each phase shifter of the second phase shifters is offset from a respective phase of a respective adjacent phase shifter of the second phase shifters in the order by a same amount prior to the adjusting, and
the respective phase for a phase shifter of the second phase shifters is offset from the respective phase of the respective adjacent phase shifter by a different amount after the adjusting.

9. The satellite transponder of claim 1, wherein each phase shifter of the first phase shifters of the first, second, and third mixing subcircuits have a same phase as a respective phase shifter of the second phase shifters of the first, second, and third mixing subcircuits prior to the adjusting.

10. A method, comprising:
sending a command to a mixing circuit of a satellite transponder that indicates for the mixing circuit to adjust respective phases of at least one of first phase shifters or second phase shifters of at least one of a first mixing subcircuit of the mixing circuit, a second mixing subcircuit of the mixing circuit, or a third mixing subcircuit of the mixing circuit;
amplifying, at a low noise amplifier of the satellite transponder, a first signal;
generating, at a local oscillator of the satellite transponder, an oscillator signal at an oscillator frequency;
frequency converting, at the mixing circuit, the first signal to a second signal, wherein the converting comprises:
dividing, at a splitter circuit of the mixing circuit, the first signal among the first mixing subcircuit, the second mixing subcircuit, and the third mixing subcircuit;
receiving, from the splitter circuit, the first signal at the respective first phase shifter of the first mixing subcircuit, the respective first phase shifter of the second mixing subcircuit, and the respective first phase shifter of the third mixing subcircuit;
outputting a first phase shifted representation of the first signal from the respective first phase shifter of the first mixing subcircuit, a second phase shifted representation of the first signal from the respective first phase shifter of the second mixing subcircuit, and a third phase shifted representation of the first signal from the respective first phase shifter of the third mixing subcircuit;
receiving, from the local oscillator, the oscillator signal at the respective second phase shifter of the first mixing subcircuit, the respective second phase shifter of the second mixing subcircuit, and the respective second phase shifter of the third mixing subcircuit;
outputting a first phase shifted representation of the oscillator signal from the respective second phase shifter of the first mixing subcircuit, a second phase shifted representation of the oscillator signal from the respective second phase shifter of the second mixing subcircuit, and a third phase shifted representation of the oscillator signal from the respective second phase shifter of the third mixing subcircuit;
receiving the first phase shifted representation of the first signal and the first phase shifted representation of the oscillator signal at a first mixer of the first mixing subcircuit, the second phase shifted representation of the first signal and the second phase shifted representation of the oscillator signal at a second mixer of the second mixing subcircuit, and the third phase shifted representation of the first signal and the third phase shifted representation of the oscillator signal at a third mixer of the third mixing subcircuit;
outputting a first component signal from the first mixer, a second component signal from the second mixer, and a third component signal-c) from the third mixer; and
summing, at a summing circuit of the mixing circuit, the first component signal, the second component signal, and the third component signal to obtain the second signal;
suppressing, at the mixing circuit, one or more harmonics of the oscillator frequency based at least in part on the adjustment of the respective phases; and
amplifying, at a power amplifier of the satellite transponder, the second signal.

11. The method of claim 10, further comprising:
amplifying, at a second low noise amplifier of the satellite transponder, a third signal, wherein the first signal and the third signal are differential pairs of signals;
dividing, at a second splitter circuit of the mixing circuit, the third signal among the first mixer, the second mixer, and the third mixer;
outputting a fourth component signal-d) from the first mixer, a fifth component signal from the second mixer, and a sixth component signal from the third mixer based at least in part on the third signal;
summing, at a second summing circuit of the mixing circuit, the fourth component signal-d), the fifth component signal, and the sixth component signal to obtain a fourth signal; and
amplifying, at a second power amplifier of the satellite transponder, the fourth signal.

12. The method of claim 11, further comprising:
adjusting a first balance adjustment circuit coupled with the first mixer to adjust a balance of the first mixer;
adjusting a second balance adjustment circuit coupled with the second mixer to adjust a balance of the second mixer; and
adjusting a third balance adjustment circuit coupled with the third mixer to adjust a balance of the third mixer.

13. The method of claim 10, further comprising:
sending a second command to the mixing circuit that indicates for the mixing circuit to adjust respective amplitudes of at least one of a first amplitude adjustment circuit of the first mixing subcircuit, a second amplitude adjustment circuit of the second mixing subcircuit, or a third amplitude adjustment circuit of the third mixing subcircuit, wherein the adjustment of the respective amplitudes is configured to suppress the one or more harmonics of the oscillator frequency.

14. The method of claim 13, wherein
the respective amplitude for the first amplitude adjustment circuit, the second amplitude adjustment circuit, and the third amplitude adjustment circuit is the same prior to the adjusting, and
the respective amplitude for a first of the first amplitude adjustment circuit, the second amplitude adjustment circuit, or the third amplitude adjustment circuit is different from the respective amplitude for a second of the first amplitude adjustment circuit, the second amplitude adjustment circuit, or the third amplitude adjustment circuit after the adjusting.

15. The method of claim 10, wherein respective amounts by which the respective phases of the at least one of the first or second phase shifters of the at least one of the first, second, or third mixing subcircuits are adjusted is based at least in part on a temperature of the satellite transponder.

16. The method of claim 10, wherein
the first phase shifters of the first, second, and third mixing subcircuits have an order,
the respective phase for each phase shifter of the first phase shifters is offset from a respective phase of a respective adjacent phase shifter of the first phase shifters in the order by a same amount prior to the adjusting, and
the respective phase for a phase shifter of the first phase shifters is offset from the respective phase of the respective adjacent phase shifter by a different amount after the adjusting.

17. The method of claim 10, wherein
the second phase shifters of the first, second, and third mixing subcircuits have an order,
the respective phase for each phase shifter of the second phase shifters is offset from a respective phase of a respective adjacent phase shifter of the second phase shifters in the order by a same amount prior to the adjusting, and
the respective phase for a phase shifter of the second phase shifters is offset from the respective phase of the respective adjacent phase shifter by a different amount after the adjusting.

18. The method of claim 10, wherein each phase shifter of the first phase shifters of the first, second, and third mixing subcircuits have a same phase as a respective phase shifter of the second phase shifters of the first, second, and third mixing subcircuits prior to the adjusting.

19. A satellite transponder, comprising:
a low noise amplifier configured to amplify a first signal associated with a first frequency range;
a local oscillator configured to generate an oscillator signal at an oscillator frequency that corresponds to a difference between a lowest frequency of the first frequency range and a lowest frequency of a second frequency range, and wherein a harmonic of the oscillator frequency is within the second frequency range; and
a mixing circuit coupled with the low noise amplifier and the local oscillator, wherein the mixing circuit is configured to frequency convert the first signal associated with the first frequency range to a second signal associated with the second frequency range, and wherein the mixing circuit comprises:
a splitter circuit coupled with the low noise amplifier and configured to divide the first signal among a first mixing subcircuit, a second mixing subcircuit, and a third mixing subcircuit;
the first mixing subcircuit comprising a respective first phase shifter configured to receive the first signal from the splitter circuit and to output a first phase shifted representation of the first signal, a respective second phase shifter configured to receive the oscillator signal and to output a first phase shifted representation of the oscillator signal, and a first mixer configured to receive the first phase shifted representation of the first signal and the first phase shifted representation of the oscillator signal and to output a first component signal;
the second mixing subcircuit comprising a respective first phase shifter configured to receive the first signal from the splitter circuit and to output a second phase shifted representation of the first signal, a respective second phase shifter configured to receive the oscillator signal and to output a second phase shifted representation of the oscillator signal, and a second mixer configured to receive the second phase shifted representation of the first signal and the second phase shifted representation of the oscillator signal and to output a second component signal;
the third mixing subcircuit comprising a respective first phase shifter configured to receive the first signal from the splitter circuit and to output a third phase shifted representation of the first signal, a respective second phase shifter configured to receive the oscillator signal and to output a third phase shifted representation of the oscillator signal, and a third mixer configured to receive the third phase shifted representation of the first signal and the third phase shifted representation of the oscillator signal and to output a third component signal; and
a summing circuit configured to sum the first component signal, the second component signal, and the third component signal to obtain the second signal; and
a power amplifier configured to amplify the second signal associated with the second frequency range.

20. The satellite transponder of claim 19, further comprising:
a second low noise amplifier coupled with the mixing circuit and configured to amplify a third signal, wherein the first signal and the third signal are differential pairs of signals, and wherein the mixing circuit further comprises:
a second splitter circuit coupled with the second low noise amplifier and configured to divide the third signal among the first mixer, the second mixer, and the third mixer, wherein each of the first mixer, the second mixer, and the third mixer is a differential mixer, wherein the first mixer is configured to output a fourth component signal based at least in part on the third signal, the second mixer is configured to output a fifth component signal based at least in part on the third signal, and the third mixer is configured to output a sixth component signal based at least in part on the third signal;
a second summing circuit configured to sum the fourth component signal, the fifth component signal, and the sixth component signal to obtain a fourth signal; and
a second power amplifier coupled with the mixing circuit and configured to amplify the fourth signal.

21. The satellite transponder of claim 20, further comprising:
a first balance adjustment circuit coupled with the first mixer, wherein the first balance adjustment circuit is configured to adjust a balance of the first mixer;
a second balance adjustment circuit coupled with the second mixer, wherein the second balance adjustment circuit is configured to adjust a balance of the second mixer; and
a third balance adjustment circuit coupled with the third mixer, wherein the third balance adjustment circuit is configured to adjust a balance of the third mixer.

22. The satellite transponder of claim 19, wherein each phase shifter of the first phase shifters of the first, second, and third mixing subcircuits have a same phase as a respective phase shifter of the second phase shifters of the first, second, and third mixing subcircuits.
